(19) United States
(12) Patent Application Publication
(10) Pub. No.: US 2023/0316074 A1
(43) Pub. Date: Oct. 5, 2023

(54) FRAMEWORK FOR SIMULATING GENERAL MULTI-SCALE PROBLEMS

(71) Applicant: Brown University, Providence, RI (US)

(72) Inventor: George E. KARNIADAKIS, Newton, MA (US)

(21) Appl. No.: 18/185,281

(22) Filed: Mar. 16, 2023

Related U.S. Application Data
(60) Provisional application No. 63/320,973, filed on Mar. 17, 2022.

(51) Int. Cl. G06F 30/20; G06N 3/08

(52) U.S. Cl. CPC G06N 3/08; G06F 30/20

(57) ABSTRACT

A data assimilation method includes providing a neural network that encodes input functions and space-time variables as inputs, pretraining the neural network, and using the pre-trained neural network to form constraints to approximate multiphysics solutions.

### STATEMENT REGARDING GOVERNMENT INTEREST

This invention was made with government support under grant number DE-SC0019453 awarded by the U.S. Department of Energy and grant number HR0011-20-9-0062 awarded by the Defense Advanced Research Projects Agency. The government has certain rights in the invention.

### CROSS REFERENCE TO RELATED APPLICATIONS

This application claims benefit from U.S. Provisional Pat. Application Serial No. 63/320,973, filed Mar. 17, 2022, which is incorporated by reference in its entirety.

### BACKGROUND OF THE INVENTION

The invention generally relates to neural networks, and in particular to a framework for simulating general multi-scale problems.

Deep learning techniques have been introduced in modeling diverse fluid mechanics problems. Overall, the recent applications of deep learning to physics modeling are based on the universal approximation theorem stating that neural networks (NNs) can be used to approximate any continuous function. However, there are other approximation theorems stating that a neural network can approximate accurately any continuous nonlinear functional or operator (a mapping from a function to another function).

### SUMMARY OF THE INVENTION

The following presents a simplified summary of the innovation in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

In an aspect, the invention features a method including providing a neural network that encodes input functions and space-time variables as inputs, pretraining the neural network, and using the pre-trained neural network to form constraints to approximate multiphysics solutions.

These and other features and advantages will be apparent from a reading of the following detailed description and a review of the associated drawings. It is to be understood that both the foregoing general description and the following detailed description are explanatory only and are not restrictive of aspects as claimed.

### BRIEF DESCRIPTION OF THE DRAWINGS

These and other aspects will now be described in detail with reference to the accompanying drawings, wherein:

FIG. 1 illustrates a table.

FIG. 2 illustrates exemplary DeepONets.

FIG. 3 illustrates a table.

FIGS. 4(a) and 4(b) illustrate exemplary DeepONets for 2D electroconvection.

FIG. 5 illustrates graphs.

FIG. 6 is a diagram of an exemplary parallel data assimilation framework (“DeepM&Mnet”).

FIG. 7 is a diagram of an exemplary series data assimilation framework (“DeepM&Mnet”).

FIG. 8 is a flow diagram.

### DETAILED DESCRIPTION OF THE INVENTION

The subject innovation is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

Electroconvection is a multiphysics problem involving coupling of the flow field with the electric field as well as the cation and anion concentration fields. For small-bye lengths, very steep boundary layers are developed, but standard numerical methods can simulate the different regimes quite accurately. Here, we use electroconvection as a benchmark problem to put forward a new data assimilation framework for simulating multiphysics and multiscale problems at speeds much faster than standard numerical methods using pre-trained neural networks (NNs). This data assimilation framework is referred to herein as “DeepM&Mnet.”

We first pre-train deep operator networks (referred herein as “DeepONets”) that can predict independently each field, given general inputs from the rest of the fields of the coupled system.

DeepONets can approximate nonlinear operators and are composed of two sub-networks, a branch net for the input fields and a trunk net for the locations of the output field. DeepONets, which are extremely fast, are used as building blocks in the DeepM&Mnet and form constraints for the multiphysics solution along with some sparse available measurements of any of the fields. The DeepM&Mnet framework is general and can be applied for building any complex multiphysics and multiscale models based on very few measurements using pre-trained DeepONets in a “plug-and-play” mode.

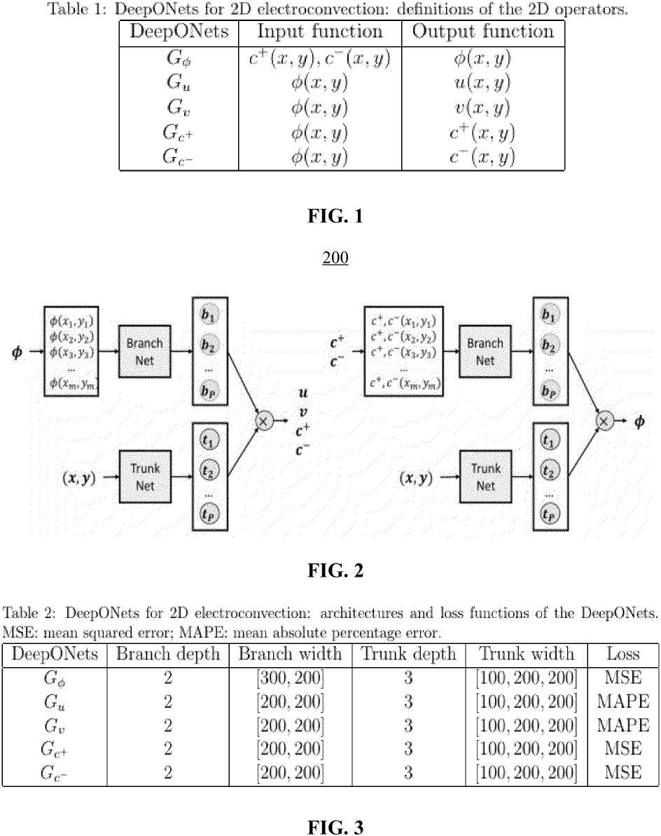

As described above, the system of the present invention uses DeepONets as the building blocks in DeepM&Mnets. The DeepONet was originally proposed for learning general nonlinear operators, including different types of partial differential equations (PDEs). Let G be an operator mapping from a space of functions to another space of functions. In this study, G is represented by a DeepONet, which takes inputs composed of two components: a function U and the location points (x, y), and outputs G(U)(x, y). According to the physics of electroconvection, we design five independent DeepONets, which are divided into two classes. The first one takes the electric potential (φ(x,y) as the input and predicts the velocity vector field (u, v) and concentration fields (c+, c-), which are denoted as Gu, Gv, Gc+ and Gc-, respectively. The second one is used to predict φ by using the cation and anion concentrations, which is represented by Gφ . The definitions of these DeepONets are given in Table 1 of FIG. 1.

Here, we apply an “unstacked” architecture for DeepONet, which is composed of a branch network and a trunk network. DeepONets are implemented in DeepXDE, a user-friendly Python library designed for scientific machine learning. The schematic diagrams of the networks 200 are illustrated in FIG. 2. In this framework, the trunk network takes the coordinates (x, y) as input and outputs [tl, t2, · · ·, tp ]T ∈ Rp . In addition, the input function, which is represented by m discrete values (e.g., [φ(x1, y1), · · ·, (φ(xm, ym )]T ), is fed into the branch network. Then the two vectors from the branch and trunk nets are merged together via a dot product to obtain the output function value. We use the fully-connected networks as the sub-networks (i.e., trunk and branch nets). The numbers of hidden layers and the number of neurons per layer of these sub-networks are given in Table 2 in FIG. 3.

The DeepONets are trained by minimizing a loss function, which measures the difference between the labels and NN predictions. In general, the mean squared error (MSE) is applied:

$$\text{MSE} = \frac{1}{N} {\sum }_{i = 1}^{N} {\left({V}_{i} - {\hat{V}}_{i}\right)}^{2} ,$$

where V represents the predicting variable, Vi and V̂i are the labeled data and the prediction, respectively; N is the number of training data. Alternatively, the mean absolute percentage error (MAPE) is also considered:

$$\text{MAPE} = \frac{1}{N} {\sum }_{i = 1}^{N} \frac{\left|{V}_{i} - {\hat{V}}_{i}\right|}{\left|{V}_{i}\right| + η} ,$$

where η is a small number to guarantee the stability when Vi = 0. The MSE loss works well in most cases, while the MAPE loss is better for the case where the output has a large range of function values. Here, we apply the MSE loss to the training of Gφ,c+,c- and apply the MAPE loss for Gu,v .

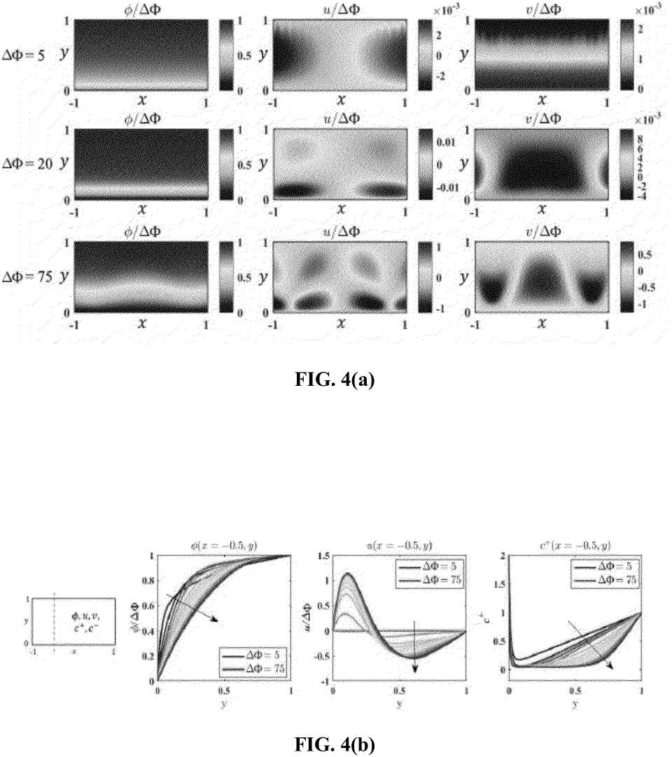

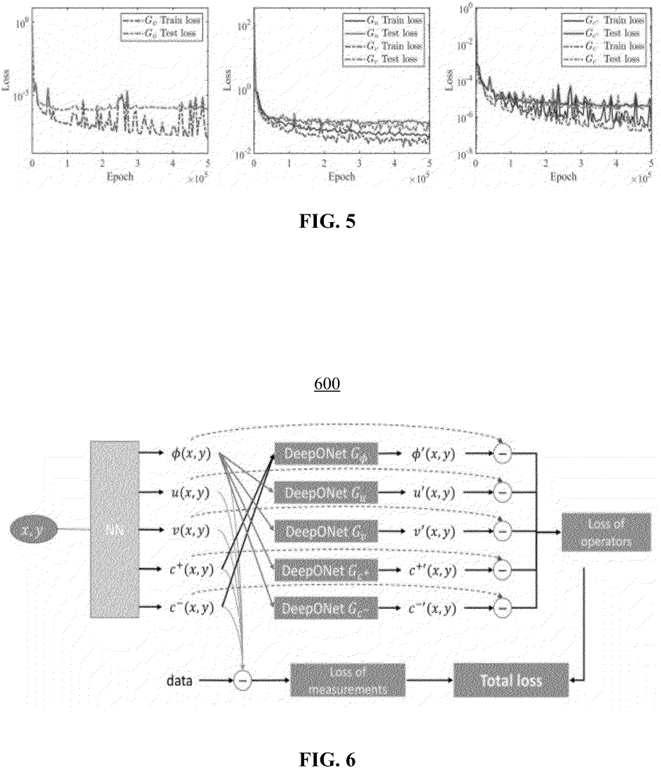

The training of DeepONets requires datasets with labeled outputs. We apply NekTar to simulate the 2D steady state fields of electroconvection problem. The computational domain is defined as Ω: x ∈ [-1, 1], y ∈ [0, 1]. Different steady-state patterns can be produced by modifying the electric potential difference ΔΦ between the boundaries. The fields of φ(x, y), c+ (x, y), c- (x, y) and velocities u(x, y), v(x, y) are collected. By modifying the boundary conditions of φ, namely using ΔΦ = 5, 10, ..., 75, we generate 15 steady states for this electroconvection problem. The 2D snapshots at various values of ΔΦ and some 1D profiles of φ(x = -0.5, y), u(x = -0.5, y), c+ (x = -0.5, y) are demonstrated in FIG. 4(a) and FIG. 4(b).

The data of φ, u, v are normalized by ΔΦ for enhanced stability in the DeepONet training. From the figures, we can find the flow pattern varies significantly with different ΔΦ. Moreover, the range of the velocity magnitude is very large (10⁻⁴ - 10⁰ ), showing the multiscale nature of this electroconvection problem.

For each 2D input field, we have 21 × 11 uniformly-distributed sensors to represent the function. As for the corresponding output fields, we randomly select 800 data points in the space for each state variable. In this context, we have N = 15 × 800 = 12000 training data points in all, where one data item is a triplet. For example, for the DeepONet Gu, one data item is [φ, (x, y), u(x, y)]. We also use NekTar to generate fields under two additional conditions, namely ΔΦ = 13.4 and ΔΦ = 62.15, which are not included in the training datasets and are used for testing and validation. The training data can be selected randomly in the computational domain. Moreover, it is possible to include the experimental measurements from sensors in the dataset. These advantages show the flexibility when preparing the data for DeepONets training.

To train the DeepONets, we apply the Adam optimizer with a small learning rate 2 × 10-4, and the networks are trained over 500,000 iterations. The activation function of the neural network is ReLU The losses of the training data and testing data during training process are presented in FIG. 5. As shown, the losses converge to small values. Note that we apply MAPE loss function to Gu,v, and thus the magnitude of their losses is different from the others. Upon training, these DeepONets can predict all fields accurately when the input functions are given.

In order to use the pre-trained DeepONets, the input function should be given. For example, the proper electric potential (φ(x, y) should be provided to Gu to obtain the u-velocity. However, this is not realistic in general. DeepM&Mnet allows us to infer the full fields of the coupled electroconvection problem when only a few measurements for any of the state variables are available. In the context of DeepM&Mnet, a neural network is used to approximate the solutions of the electroconvection, while the pre-trained DeepONets are applied as the constraints of the solutions.

In a first embodiment, as shown in FIG. 6, a schematic diagram of the parallel DeepM&Mnet architecture 600 is illustrated. In this context, a fully-connected network with trainable parameters is used to approximate the coupling solutions. This is an ill-posed problem since only a few measurements are available. Therefore, regularization is required to avoid overfitting. Here, the pre-trained DeepONets are applied to deal with this problem. The pre-trained DeepONets are fixed (not trainable) and considered as the constraints of the NN outputs, which can be seen in FIG. 6. The neural network, which takes (x, y) as inputs and outputs (φ, u, v, c+, c- ), is trained by minimizing the following loss function:

$$arg {min}_{θ} L = {\text{λ}}_{d} {L}_{d a t a} + {\text{λ}}_{o} {L}_{o p} + {\text{λ}}_{r} {L}_{2} \left(θ\right) ,$$

where λd, λo and λr are the weighting coefficients of the loss function; L2 (θ) =k θ k2 is the L2 regulatization of the trainable parameters θ, which can help avoid overfitting and stabilize the training process2 ; and

$${L}_{d a t a} = {\sum }_{V ∈ \left(O , u , x , {c}^{4} , {c}^{-}\right)} \frac{1}{{N}_{d}} {\sum }_{i = 1}^{{N}_{d}} \left(V \left({x}^{4} , {y}^{4}\right) - {V}_{d a t a} \left({x}^{i} , {y}^{i}\right)\right) ,$$

$${L}_{o p} = {\sum }_{V ∈ \left(ϕ , u , x , {c}^{4} , {c}^{-}\right)} \frac{1}{{N}_{o p}} {\sum }_{i = 1}^{{N}_{o p}} \left(V \left({x}^{4} , {y}^{4}\right) - {V}_{d a t a} \left({x}^{i} , {y}^{i}\right)\right) ,$$

where Ldata is the data mismatch and Lop is the difference between the neural network outputs and the DeepONets outputs. V can be any variables of the investigated solutions (φ, u, v, c+, c- ); V (xi, yi ) accounts for the output of the fully-connected network, while V 0 (xi, y i ) is the output of DeepONet. Nd and Nop denote the number of measurements for each variable and the number of points for evaluating the operators, respectively. Here, we would like to add some comments on DeepM&Mnet. First, it is not necessary to have measurements for every variable. For example, if measurements are only available for φ, the DeepONets Gu, Gv, Gc+ and Gc- can provide constraints for the other variables and guide the NN outputs to the correct solutions. Second, the framework of parallel DeepM&Mnet 600 (FIG. 6), we do not only have the outputs the fully-connected network V ∈ {φ, u, v, c+, c-}, but also the outputs of DeepONets V 0 ∈ {φ0, u0, v0, c+0, c-0}. Ideally, V and V 0 should converge to the same values. However, there is bias between V and V 0 due to the approximation error of the pre-trained DeepONets and the optimization error of the neural network.

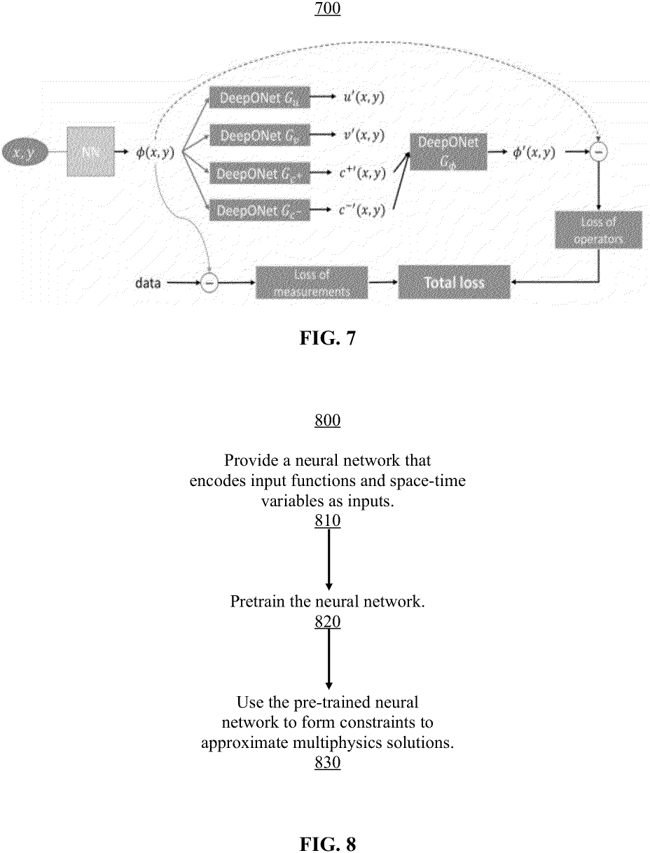

In a second embodiment, as shown in FIG. 7, a schematic diagram of the series DeepM&Mnet architecture 700 is illustrated. In this embodiment, the fully-connected network is only used to approximate φ. The other variables (i.e., u, v, c+, c- ) are the hidden outputs in this framework and given by the DeepONets based on the result of φ. Moreover, with the pre-trained DeepONet Gφ, we can generate φ0 from (c+O, c-0). The loss function is similar to (4). However, here we assume that we only have the measurements of φ, and Lop only contains the φ operator, thus:

$${L}_{d a t a} = \frac{1}{{N}_{d}} {\sum }_{i = 1}^{{N}_{d}} \left(ϕ \left({x}^{4} , {y}^{4}\right) - {ϕ}_{d a t a} \left({x}^{i} , {y}^{i}\right)\right) ,$$

$${L}_{o p} = \frac{1}{{N}_{o p}} {\sum }_{i = 1}^{{N}_{o p}} \left(ϕ \left({x}^{4} , {y}^{4}\right) - {ϕ}^{′} \left({x}^{i} , {y}^{i}\right)\right) ,$$

Different from the parallel architecture 600, in the series DeepM&Mnet 700, V only represents φ, while V 0 ∈ {φ0, u0, v0, c+0, c-0}. This framework 700 shows that given a few measurements of φ, the neural network can produce the full field of φ. All other fields can be obtained by the pre-trained DeepONets inside the loop.

In summary, the DeepM&Mnet enables integration of pre-trained DeepONets and a few measurements from any of the fields to produce the full fields of the coupled system. In DeepM&Mnets, a neural network is used as the surrogate model of the multiphysics solutions, and uses the pre-trained DeepONets as the constraints for the solutions. For both parallel and series DeepM&Mnets, we find that only a few measurements are sufficient to infer the full fields of the electroconvection, even if measurements are not available for all state variables. The DeepM&Mnet, which can be considered as a simple data assimilation framework, is much more flexible and efficient than any other conventional numerical method in terms of dealing with such assimilation problem. In order to use the DeepM&Mnets, the building blocks—the DeepONets—are required to be pre-trained with labeled data. However, preparing the training data is very flexible and the training can be done offline. Once the DeepONets have been trained and embedded in the DeepM&Mnet, it is straightforward to predict the solutions of a complex multiphysics and multiscale system when only a few measurements are available. The results show that the new framework can be used for any type of multiphysics and multiscale problems.

As shown in FIG. 8, a data assimilation process 800 includes providing (810) a neural network that encodes input functions and space-time variables as inputs.

Process 800 includes pretraining (820) the neural network.

Process 800 includes using (830) the pre-trained neural network to form constraints to approximate multiphysics solutions.

The neural network can include a branch sub-network for encoding the input function at a fixed number of sensors, and a truck sub-net for encoding locations for output functions.

Two vectors from the branch sub-net and the trunk sub-net can be merged together via a dot product to obtain an output function value.

Although only a few embodiments have been disclosed in detail above, other modifications are possible. All such modifications are intended to be encompassed within the following claims.

What is claimed is:

1. A data assimilation method comprising:
providing a neural network that encodes input functions and space-time variables as inputs;
pretraining the neural network; and
using the pre-trained neural network to form constraints to approximate multiphysics solutions.

2. The data assimilation method of claim 1 wherein the neural network comprises:
a branch sub-network for encoding the input function at a fixed number of sensors; and
a truck sub-net for encoding locations for output functions.

3. The data assimilation method of claim 2 wherein two vectors from the branch sub-net and the trunk sub-net are merged together via a dot product to obtain an output function value.

4. The data assimilation method of claim 3 wherein the one of the plurality of multiphysics problems comprises forecasting, the forecasting comprising predicting a time and a space of a state of a system.

5. The data assimilation method of claim 3 wherein the one of the plurality of multiphysics problems comprises interrogating a system with different input scenarios to optimize design parameters of the system.

6. The data assimilation method of claim 3 wherein the one of the plurality of multiphysics problems comprises actuating a system to achieve efficiency/autonomy.

7. The data assimilation method of claim 3 wherein the one of the plurality of multiphysics problems comprises identifying system parameters and discovering unobserved dynamics.

8. The data assimilation method of claim 3 wherein the one of the plurality of multiphysics problems comprises forecasting applications.

9. The data assimilation method of claim 8 wherein the forecasting applications include airfoils, solar thermal systems, VIV, material damage, path planning, material processing applications, additive manufacturing, structural health monitoring and infiltration.

10. The data assimilation method of claim 3 wherein the one of the plurality of multiphysics problems comprises design applications.

11. The data assimilation method of claim 10 wherein the design applications include airfoils, material damage and structural health monitoring.

12. The data assimilation method of claim 3 wherein the one of the plurality of multiphysics problems comprises control/autonomy applications.

13. The data assimilation method of claim 12 wherein the control/autonomy applications include airfoils, electro-convection and path planning.

14. The data assimilation method of claim 3 wherein the one of the plurality of multiphysics problems comprises identification/discovery applications.

15. The data assimilation method of claim 14 wherein the identification/discovery applications include VIV, material damage and electro-convention.

16. The data assimilation method of claim 3 wherein the one of the plurality of multiphysics problems comprises resin transfer molding (RTM) applications.
